(19) United States
(12) Patent Application Publication
(10) Pub. No.: US 2025/0089196 A1
(43) Pub. Date: Mar. 13, 2025

(54) POWER EQUIPMENT

(71) Applicant: Delta Electronics (Shanghai) Co., Ltd., Shanghai (CN)

(72) Inventors: Yansong Lu, Shanghai (CN); Jun Chen, Shanghai (CN); Wei Wang, Shanghai (CN); Shisheng Hou, Shanghai (CN)

(21) Appl. No.: 18/825,056

(22) Filed: Sep. 5, 2024

(30) Foreign Application Priority Data
Sep. 7, 2023 (CN) 202311156993.7

(51) Int. Cl. H05K 7/14; H05K 7/18; H05K 7/20

(52) U.S. Cl. CPC H05K 7/1457; H05K 7/18; H05K 7/20145

(57) ABSTRACT

A power equipment is disclosed. The power equipment includes an installation cabinet and a plurality of power modules. The installation cabinet includes a top. The plurality of power modules includes a first set of power modules and a second set of power modules. The first set of power modules is electrically connected to the installation cabinet, arranged adjacent to each other, and detachably disposed on the on the top of the installation cabinet to form a first array. The second set of power modules is electrically connected to the installation cabinet, arranged adjacent to each other, and detachably disposed on the on the top of the installation cabinet to form a second array. The power modules in the first array and the power modules in the second array are arranged back-to-back.

### CROSS-REFERENCE TO RELATED APPLICATION

This application claims priority to China Patent Application No. 202311156993.7, filed on Sep. 7, 2023. The entire contents of the above-mentioned patent application are incorporated herein by reference for all purposes.

### FIELD OF THE INVENTION

The present disclosure relates to a power equipment, and more particularly to a power equipment that is easy to transport.

### BACKGROUND OF THE INVENTION

As the energy demand continues to develop, the requirements for output power of the power equipment are increased. The conventional power equipment is integrally assembled. That is, the parts are assembled into a main body in the factory in advance, and then the main body is directly transported to the installation site. However, a standard container generally has fixed dimensions. Moreover, the conventional power equipment has a large appearance and a large footprint. In that, the transportation efficiency is reduced and the transportation resources are wasted.

In addition, two or more power equipment are used in parallel to increase the output power in the conventional method. However, this method requires the external terminals of the power equipment to be connected in parallel, and then electrically connected to the transformer. Moreover, each power equipment needs to be packaged and transported separately. The cost is higher. During installation, sufficient space should be reserved between two or more power equipment, and the space required is large. During maintenance, each power equipment needs to be maintained separately. It increases the maintenance costs.

On the other hand, the power modules in the conventional power equipment are arranged in a relatively compact manner. It results in insufficient heat dissipation space between the power modules, and the heat dissipation efficiency is reduced. The power modules in the conventional power equipment have a modular structure. But limited by the size of the main body and the installation method thereof, it is unable to adjust the layout of the power modules according to the requirements.

Therefore, there is a need of providing a power equipment to obviate the drawbacks encountered by the prior arts.

### SUMMARY OF THE INVENTION

An object of the present disclosure is to provide a power equipment for achieving the effects of increasing output power, improving the transportation efficiency, saving the transportation resources and improving the heat dissipation efficiency.

An object of the present disclosure is to provide a power equipment includes an installation cabinet and a plurality of power modules. The installation cabinet includes a top. The plurality of power modules includes a first set of power modules and a second set of power modules, the first set of power module is electrically connected to the installation cabinet, arranged adjacent to each other, and detachably disposed on the top of the installation cabinet to form a first array, and the second set of power module is electrically connected to the installation cabinet, arranged adjacent to each other, and detachably disposed on the top of the installation cabinet to form a second array. The power modules in the first array and the power modules in the second array are arranged back-to-back.

In an embodiment, the installation cabinet and the plurality of power modules are assembled as a main body for transportation.

In an embodiment, each of the plurality of power modules is disposed on the top of the installation cabinet through an installation bracket.

In an embodiment, one of the power modules in the first array and a corresponding one of the power modules in the second array are arranged back-to-back, and the two power modules arranged back-to-back are installed on the top of the installation cabinet through an identical one of the installation brackets.

In an embodiment, the power modules in the first array are disposed on a front side of the top of the installation cabinet, and the power modules in the second array are disposed on a rear side of the top of the installation cabinet.

In an embodiment, the installation cabinet includes a plural sets of interfaces, and the plural sets of interfaces include a first row of interfaces and a second row of interfaces; the first row of interfaces is disposed in a front side of the installation cabinet, and each of the first row of interfaces is corresponding to one of the power modules in the first array; the second row of interfaces is disposed in a rear side of the installation cabinet, and each of the second row of interfaces is corresponding to one of the power modules in the second array, and each of the plural sets of interfaces includes a first interface, a second interface and a third interface.

In an embodiment, the installation cabinet includes a first warehouse disposed on a front edge of the installation cabinet and a second warehouse disposed on a rear edge of the installation cabinet; the first warehouse includes a first DC warehouse, a first AC warehouse disposed adjacent to the first DC warehouse, and a first wiring warehouse in communication with and installed on tops of the first DC warehouse and the first wiring warehouse, and the second warehouse includes a second DC warehouse, a second AC warehouse disposed adjacent to the second DC warehouse, and a second wiring warehouse in communication with and disposed on tops of the second DC warehouse and the second AC warehouse.

In an embodiment, each of the first DC warehouse and the second DC warehouse includes a plural sets of DC bus bars and a plural sets of DC cables disposed therein. Each of the plural sets of DC cables includes a first end electrically connected to one of the plural sets of DC bus bars, and a second end reserved in the first wiring warehouse or the second wiring warehouse. After the power module is assembled, the second end of each of the plural sets of DC cables passes through the first interface in a corresponding one of the plural sets of interfaces and is electrically connected to a DC side of the power module.

In an embodiment, each of the first AC warehouse and the second AC warehouse includes a plural sets of AC terminals and a plural sets of AC cables disposed therein. Each of the plural sets of AC cables includes a first end electrically connected to one of the plural sets of AC terminals, and a second end reserved in the first wiring warehouse or the second wiring warehouse. After the power module is assembled, the second end of each of the plural sets of AC cables passes through the second interface in a corresponding one of the plural sets of interfaces and is electrically connected to an AC side of the power module.

In an embodiment, the first AC warehouse or the second AC warehouse includes a control box and a plural sets of control cables disposed therein. Each of the plural sets of control cables includes a first end electrically connected to the control box, and a second end reserved in the first wiring warehouse or the second wiring warehouse. After the power module is assembled, the second end of each of the plural sets of control cables passes through the third interface in a corresponding one of the plural sets of interfaces and is electrically connected to a control board of the power module.

In an embodiment, a number of the power modules in the first array is equal to a number of the power modules in the second array.

In an embodiment, the installation cabinet includes a bottom structure and a transport panel, and the transport panel is connected to the bottom structure for transportation.

In an embodiment, when the power equipment is transported to an installation site, the transport panel is removed, and the bottom structure is fixed to a base in the installation site.

In an embodiment, the power equipment further includes a plurality of first air ducts and a second air duct, the plurality of first air ducts are located on top sides of the plurality of power modules, and the second air duct is located on bottom sides of the plurality of power modules. Cold air is inhaled into the power modules through the second air duct, and hot air is discharged out from the power modules through the plural first air ducts.

In an embodiment, the plurality of first air ducts include a front air duct disposed and corresponding to a front side of the first array, a middle air duct located between the first array and the second array, and a rear air duct disposed and corresponding to a rear side of the second array.

In an embodiment, the installation bracket has a height, and at least part of the second air duct is formed between the installation cabinet and the plurality of power modules.

In an embodiment, the installation bracket includes a partition, and at least part of the second air duct is located among the partition, the first array and the second array.

In an embodiment, the height of the installation bracket is adjusted to adjust a volume of the second air duct.

In an embodiment, a position of the partition is adjusted to adjust a volume of the second air duct.

The beneficial effect of the present disclosure is that the embodiments of the present invention provide a power equipment. The plurality of power modules are arranged in double-row array and detachably disposed on the top of the installation cabinet to increase the total output power. The plurality of power modules and the installation cabinet are assembled to form a main body for transportation. It helps to improve the transportation efficiency of the power equipment, save the transportation resources, and further improve the heat dissipation efficiency.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective view illustrating a power equipment according to a first embodiment of the present disclosure;

FIG. 2 is a structural exploded view illustrating the power equipment of FIG. 1, and the cables in the installation cabinet are hidden;

FIG. 3 is a perspective view illustrating the installation bracket of the power equipment of FIG. 1;

FIG. 4 is a top view illustrating the power equipment of FIG. 1 connected to a transformer;

FIG. 5 is a perspective view illustrating the installation cabinet of the power equipment of FIG. 1;

FIG. 6 is a perspective view illustrating the installation cabinet of FIG. 5, and the top of the installation cabinet, the front side panel, the left side panel and the cables are hidden;

FIG. 7 is a perspective view illustrating the DC bus bars in the power equipment of FIG. 6;

FIG. 8 is a perspective view illustrating the AC bus bars in the power equipment of FIG. 6;

FIG. 9 is a lateral view illustrating a power equipment according to a second embodiment of the present disclosure, wherein the cables are hidden; and

FIG. 10 is a perspective view illustrating the installation cabinet and the installation bracket of the power equipment of FIG. 9.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “approximately” or “substantially” decorator. Accordingly, unless otherwise indicated, the numerical parameters of the present invention and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

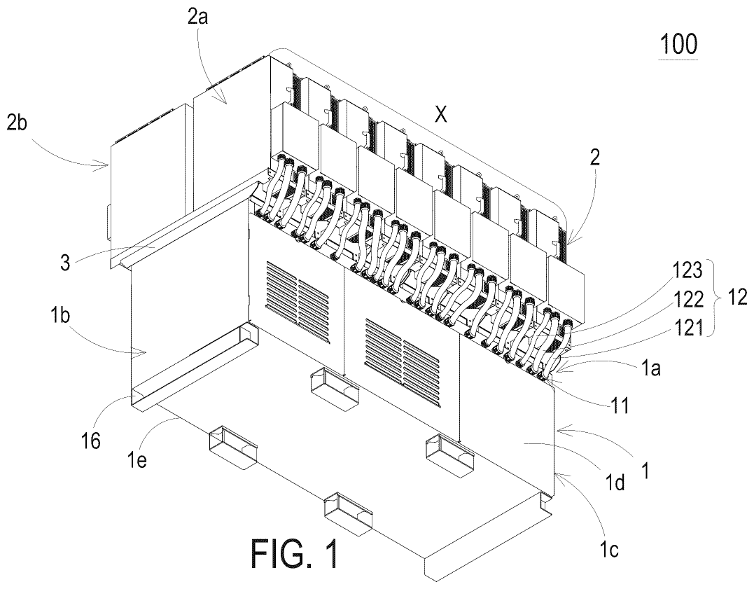

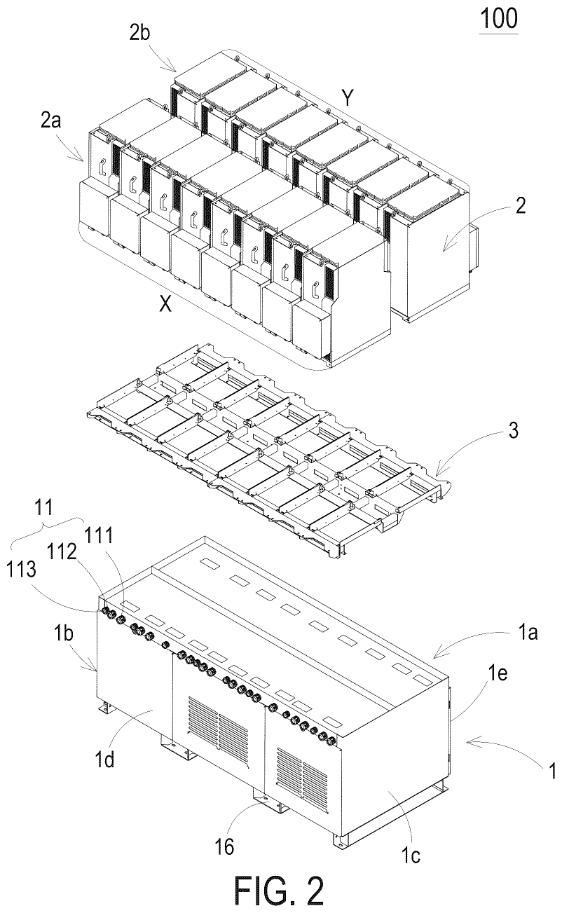

FIG. 1 is a perspective view illustrating a power equipment according to a first embodiment of the present disclosure. FIG. 2 is a structural exploded view illustrating the power equipment of FIG. 1, and the cables in the installation cabinet are hidden. As shown in FIG. 1 and FIG. 2, in the embodiment, the power equipment 100 includes an installation cabinet 1 and a plurality of power modules 2. The installation cabinet 1 includes a top 1a. The plurality of power modules 2 includes a first set of power modules 2a and a second set of power modules 2b. The first set of power modules 2a are electrically connected to the installation cabinet 1, arranged adjacent to each other, and detachably disposed on the top 1a of the installation cabinet 1 to form a first array X. The second set of power modules 2b are electrically connected to the installation cabinet 1, arranged adjacent to each other, and detachably disposed on the top 1a of the installation cabinet 1 to form a second array Y. The power modules 2 in the first array X and the power modules 2 in the second array Y are arranged back-to-back. With the arrangement of the first set of power modules 2a and the second set of power modules 2b, the effect of increasing the total output power is achieved.

In the embodiment, the installation cabinet 1 and the plurality of power modules 2 are assembled as a main body for transportation. In the embodiment, the size of the main body is, for example, but not limited to, a hexahedral structure with a length of 2910 mm, a width of 1974 mm, and a height of 2350 mm. In the embodiment, two main bodies are accommodated in a general standard container, and then transported to an installation site. Thereby, the transportation efficiency of the power equipment 100 is improved, and the transportation resources are saved.

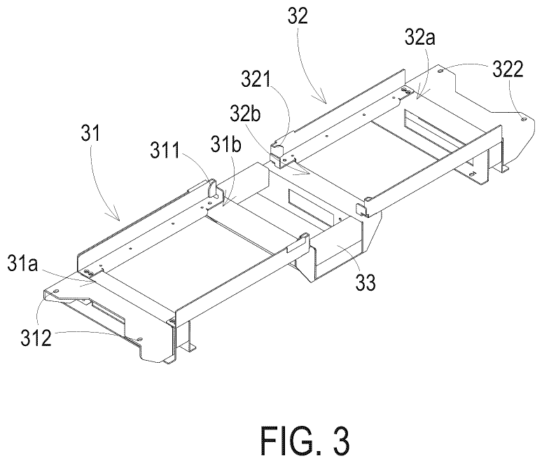

FIG. 3 is a perspective view illustrating the installation bracket of the power equipment of FIG. 1. As shown in FIG. 1 to FIG. 3, in the embodiment, the power equipment 100 further includes a plurality of installation brackets 3. Each of the plurality of power modules 2 is disposed on the top 1a of the installation cabinet 1 through one installation bracket 3. In the embodiment, one of the power modules 2 in the first array X and a corresponding one of the power modules 2 in the second array Y are arranged back-to-back, and the two power modules 2 arranged back-to-back are installed on the top 1a of the installation cabinet 1 through an identical one of the installation brackets 3.

In the embodiment, the number of the power modules 2 in the first array X is eight, and the number of the power modules 2 in the second array Y is also eight. In an embodiment, the number of the power modules 2 in the first array X is equal to the number of the power modules 2 in the second array Y, but the present disclosure is not limited thereto. In the embodiment, the power of each power module 2 is, for example but not limited to, 1.6 megawatts (MW). Compared with two independent power equipment (not shown) with eight power modules in a single row, the present disclosure provides the eight power modules 2 in the first array X and the eight power modules 2 in the second array Y arranged back-to-back, so that the volume of the power equipment 100 is reduced by at least one-third and the footprint is smaller.

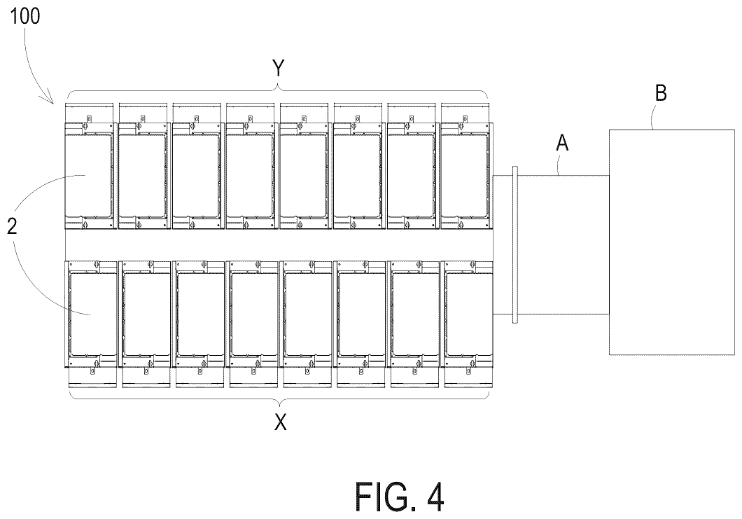

FIG. 4 is a top view illustrating the power equipment of FIG. 1 connected to a transformer. As shown in FIG. 4, in the embodiment, the power modules 2 in the first array X and the power modules 2 in the second array Y of the power equipment 100 are directly connected to the transformer B through the connection bus A without the need for parallel connection. The installation method is simple, convenient and fast. In an embodiment, the power modules 2 can be packaged and transported separately to save transportation costs.

As shown in FIG. 1 to FIG. 3, in the embodiment, the plurality of installation brackets 3 are arranged in an array and detachably disposed on the top 1a of the installation cabinet 1. Each installation bracket 3 includes a first guiding rail 31 and a second guiding rail 32. The first guiding rail 31 includes a first end 31a, a second end 31b, a slot 311 and at least one fixing hole 312. The second guiding rail 32 includes a first end 32a and a second end 32b, a slot 321 and at least one fixing hole 322. A connection portion 33 is connected between the second end 31b of the first guiding rail 31 and the second end 32b of the second guiding rail 32. The first end 31a of the first guiding rail 31 and the first end 32a of the second guiding rail 32 are respectively arranged in the direction away from the connection portion 33. The slot 311 of the first guiding rail 31 is disposed at the second end 31b, and at least one fixing hole 312 of the first guiding rail 31 is disposed at the first end 31a. The power module 2 is slid from the first end 31a of the first guiding rail 31 toward the second end 31b, and locked in the slot 311. Then, the power module 2 is fixed to the at least one fixing hole 312 through bolts (not shown). The slot 321 of the second guiding rail 32 is disposed at the second end 32b, and the at least one fixing hole 322 of the second guiding rail 32 is disposed at the first end 32a. The power module 2 is slid from the first end 32a of the second guiding rail 32 toward the second end 32b, and is locked in the slot 321. Then, the power module 2 is fixed to the at least one fixing hole 322 through bolts (not shown). With the arrangement of the first guiding rail 31 and the second guiding rail 32 on the installation bracket 3, the power modules 2 are quickly fixed to the top 1a of the installation cabinet 1.

As shown in FIG. 1 and FIG. 2, in the embodiment, the power modules 2 in the first array X are disposed on a front side of the top 1a of the installation cabinet 1. The power modules 2 in the second array Y are disposed on a rear side of the top 1a of the installation cabinet 1. In the embodiment, the installation cabinet 1 includes a first lateral side 1b, a second lateral side 1c, a front side 1d and a rear side 1e. The first lateral side 1b and the second lateral sides 1c are two opposite lateral sides of the installation cabinet 1. The front side 1d and the rear side 1e are two opposite side of the installation cabinet 1, and connected between the first lateral side 1b and the second lateral side 1c, respectively.

In the embodiment, the installation cabinet 1 includes plural sets of interfaces 11 and plural sets of cables 11. The plural sets of interfaces 11 includes a first row of interfaces and a second row of interfaces. The first row of interfaces is disposed in the front side 1d of the installation cabinet 1, and each of the first row of interfaces 11 is corresponding to one of the power modules 2 in the first array X. The second row of interfaces is disposed in a rear side 1e of the installation cabinet 1, and each of the second row of interfaces 11 is corresponding to one of the power modules 2 in the second array Y. The plural sets of cables 12 are reserved in the installation cabinet 1. After the power module 2 is installed on the top 1a of the installation cabinet 1, at least part of the cables 12 pass through the interfaces 11 in the first row of interfaces to electrically connect the plurality of power modules 2 in the first array X. The remaining cables 12 are electrically connected to the plurality of power modules 2 in the second array Y through the interfaces 11 in the second row of interfaces. With the arrangement of the plural sets of interfaces 11 corresponding to the plurality of power modules 2 respectively, the wiring paths of the cables 12 are shortened and it is easy to assemble.

As shown in FIG. 1 to FIG. 2, in the embodiment, each of the plural sets of interfaces 11 includes a first interface 111, a second interface 112 and a third interface 113. Each of the plural sets of cables 12 includes a DC cable 121, an AC cable 122 and a control cable 123. Preferably but not exclusively, the first interface 111, the second interface 112 and the third interface 113 are cable glands. Each of the plural sets of interfaces 11 includes a plurality of sealing covers (not shown). Before the power module 2 is installed in the installation cabinet 1, the plurality of sealing covers are pre-blocked on the first interface 111, the second interface 112 and the third interface 113, so as to achieve the waterproof and dustproof effects during transportation. During the assembling process of the power module 2, the sealing covers are removed from the first interface 111, the second interface 112 and the third interface 113. The DC cable 121, the AC cable 122 and the control cable 123 pass through the first interface 111, the second interface 112 and the third interface 113 respectively, and are electrically connected to the power module 2.

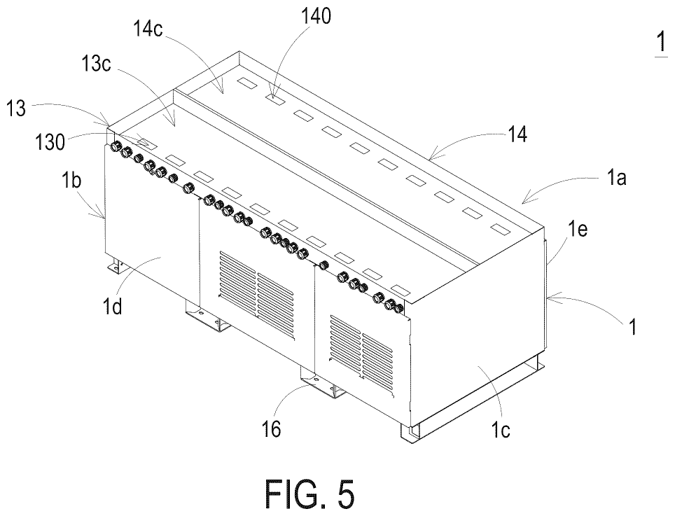

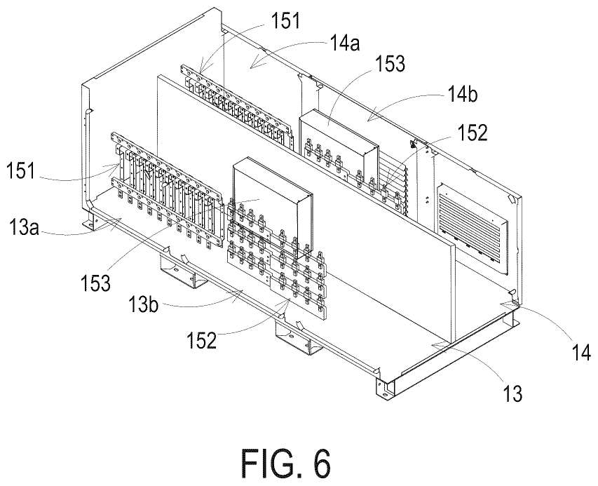

FIG. 5 is a perspective view illustrating the installation cabinet of the power equipment of FIG. 1. FIG. 6 is a perspective view illustrating the installation cabinet of FIG. 5, and the top of the installation cabinet, the front side panel, the left side panel and the cables are hidden. As shown in FIG. 1 to FIG. 6, in the embodiment, the installation cabinet 1 includes a first warehouse 13 and a second warehouse 14. The first warehouse 13 is disposed on a front edge of the installation cabinet 1 and is corresponding to the first array X, and the second warehouse 14 is disposed on a rear edge of the installation cabinet 1 and is corresponding to the second array Y. The first warehouse 13 includes a first DC warehouse 13a, a first AC warehouse 13b and a first wiring warehouse 13c. The first DC warehouse 13a is disposed adjacent to the first AC warehouse 13b, and the first wiring warehouse 13c is in communication with the first DC warehouse 13a and the first AC warehouse 13b through a plurality of holes 130, and installed on tops of the first DC warehouse 13a and the first AC warehouse 13b. The second warehouse 14 includes a second DC warehouse 14a, a second AC warehouse 14b and a second wiring warehouse 14c, the second DC warehouse 14a is disposed adjacent to the second AC warehouse 14b, and the second wiring warehouse 14c is in communication with the second DC warehouse 14a and the second AC warehouse 14b through a plurality of holes 140, and disposed on tops of the second DC warehouse 14a and the second AC warehouse 14b. In the embodiment, the first warehouse 13 and the second warehouse 14 are separated from each other, but the present disclosure is not limited thereto.

In an embodiment, the first warehouse 13 and the second warehouse 14 of the installation cabinet 1 are not separated and in communication with each other. The present disclosure is not limited thereto. Preferably but not exclusively, in an embodiment, a hollow partition is disposed between the first warehouse 13 and the second warehouse 14. In an embodiment, the first warehouse 13 and the second warehouse 14 of the installation cabinet 1 are partially in communication with each other. Preferably but not exclusively, the first DC warehouse 13a of the first warehouse 13 is in communication with the second DC warehouse 14a of the second warehouse 14. The first AC warehouse 13b of the first warehouse 13 is in communication with the second AC warehouse 14b of the second warehouse 14. Alternatively, the first wiring warehouse 13c of the first warehouse 13 is in communication with the second wiring warehouse 14c of the second warehouse 14. The present disclosure is not limited thereto. The connection method between the first warehouse 13 and the second warehouse 14 is adjustable according to the practical requirements.

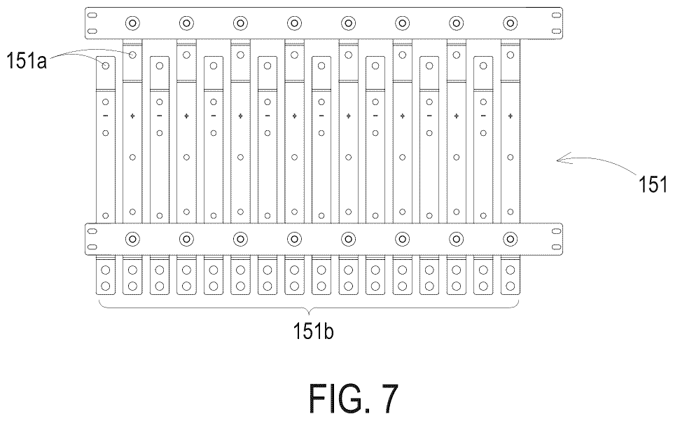

FIG. 7 is a perspective view illustrating the DC bus bars in the power equipment of FIG. 6. As shown in FIG. 1 to FIG. 7, in the embodiment, each of the first DC warehouse 13a and the second DC warehouse 14a includes a plural sets of DC bus bars 151 and a plural sets of DC cables 121 disposed therein. Preferably but not exclusively, eight sets of DC bus bars 151 are respectively disposed in the first DC warehouse 13a and the second DC warehouse 14a. Each of the plural sets of DC bus bars 151 includes a set of DC terminals 151a. The plural sets of DC bus bars 151 are arranged adjacent to each other to form a DC bus bar array 151b.

Each of the plural sets of DC cables 121 includes a first end (not shown) electrically connected to one of the DC terminals 151a of the plural sets of DC bus bars 151 and is led into the first wiring warehouse 13c through the hole 130 or the second wiring warehouse 14c through the hole 140 from bottom to top, and includes a second end 121b reserved in the first wiring warehouse 13c or the second wiring warehouse 14c. After the power module 2 is assembled on the top 1a of the installation cabinet 1, the second end 121b of each of the plural sets of DC cables 121 passes through the first interface 111 in a corresponding one of the plural sets of interfaces 11 and is electrically connected to a DC side (not shown) of the power module 2, as shown in FIG. 1. In that, the transmission of direct current is achieved.

As shown in FIG. 1 to FIG. 7, in the embodiment, one side of the DC bus bar array 151b faces the first lateral side 1b, and another side of the DC bus bar array 151b faces the second lateral side 1c. Each set of DC terminals 151a is disposed adjacent to a corresponding set of interfaces 11 located on the front side 1d or the rear side 1e, so that the wiring path of the DC cable 121 is shortened.

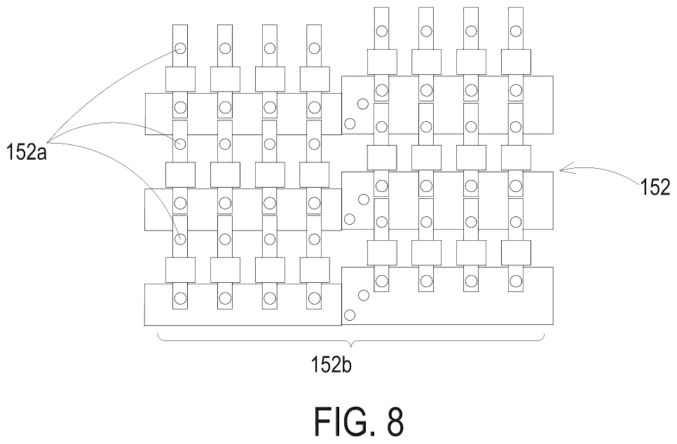

FIG. 8 is a perspective view illustrating the AC bus bars in the power equipment of FIG. 6. As shown in FIG. 1 to FIG. 6 and FIG. 8, in the embodiment, each of the first AC warehouse 13b and the second AC warehouse 14b includes three AC bus bars 152 and plural sets of AC cables 122 disposed therein. Each set of the AC bus bar 152 includes a plurality of AC terminals for forming plural sets of AC terminals 152a. Preferably but not exclusively, each of the first AC warehouse 13b and the second AC warehouse 14b includes eight sets of AC terminals 152a, respectively. The plural sets of AC terminals 152a are arranged and disposed adjacent to each other to form an AC terminal array 152b. Each of the plural sets of AC cables 122 includes a first end (not shown) electrically connected to one of the plural sets of AC terminals 152a and is led into the first wiring warehouse 13c through the hole 130 or the second wiring warehouse 14c through the hole 140 from bottom to top, and includes a second end 122b reserved in the first wiring warehouse 13c or the second wiring warehouse 14c. After the power module 2 is assembled on the top 1a of the installation cabinet 1, the second end 122b of each of the plural sets of AC cables 122 passes through the second interface 112 in a corresponding one of the plural sets of interfaces 11 and is electrically connected to an AC side (not shown) of the power module 2, as shown in FIG. 1. In that, the transmission of alternating current is achieved.

As shown in FIG. 1 to FIG. 6 and FIG. 8, in the embodiment, one side of the AC terminal array 152b faces the first lateral side 1b, and another side of the AC terminal array 152b faces the second lateral side 1c. Each set of AC terminals 152a is disposed adjacent to a corresponding set of the interfaces 11 located on the front side 1d or the rear side 1e, so that the wiring path of the AC cable 122 is shortened.

In the embodiment, each of the first AC warehouse 13b and the second AC warehouse 14b includes a control box 153 and a plural sets of control cables 123 disposed therein. Each of the plural sets of control cables 123 includes a first end (not shown) electrically connected to the control box 153 and is led into the first wiring warehouse 13c through the hole 130 or the second wiring warehouse 14c through the hole 140 from bottom to top, and includes a second end 123b reserved in the first wiring warehouse 13c or the second wiring warehouse 14c. After the power module is assembled on the top 1a of the installation cabinet 1, the second end 123b of each of the plural sets of control cables 123 passes through the third interface 113 in a corresponding one of the plural sets of interfaces 11 and is electrically connected to a control board (not shown) of the power module 2, as shown in FIG. 1. In that, the transmission of the signal is achieved.

In an embodiment, the installation cabinet 1 further includes at least one protection warehouse (not shown). The protection warehouse is disposed between the first AC warehouse 13b and the second lateral side 1c, or between the second AC warehouse 14b and the second lateral side 1c. Moreover, the protection warehouse includes plural sets of circuit breakers (not shown). The plural sets of circuit breakers in the protection warehouse are connected to the AC bus bars 152 in the first AC warehouse 13b or the second AC warehouse 14b to protect the circuit and avoid the overload, the short circuit and other situations.

In an embodiment, the plurality of power modules 2 are modular modules and include standard modules (not shown), which is beneficial to rapid manufacturing and production. In an embodiment, the power module 2 further includes functional modules (not shown). The functional module of the power module 2 has additional functions, and its functional configuration can be customized by customers or adjusted according to the practical requirements to achieve functional diversification.

In an embodiment, the installation cabinet 1 includes a bottom structure 16 and a transport panel (not shown). The transport panel is connected to the bottom structure 16 for transportation. Thereby, the installation cabinet 1 is fixed to avoid the collision during transportation. In an embodiment, the transport panel is, for example but not limited to, a wooden board, which is detachably matched with the bottom structure 16. When the power equipment 100 is transported to an installation site, the transport panel is removed, and the bottom structure 16 is fixed to a base (not shown) in the installation site. The bottom structure 16 is fixed and matched with the base in the installation site, thereby achieving rapid assembling and positioning.

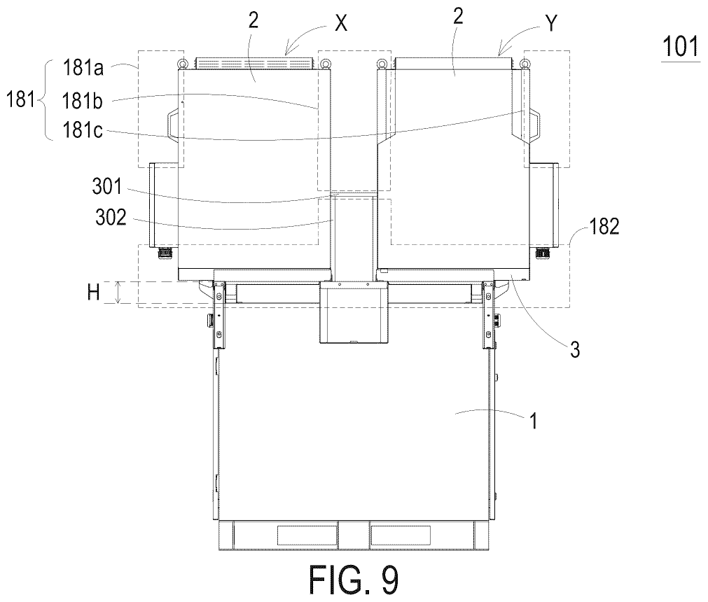

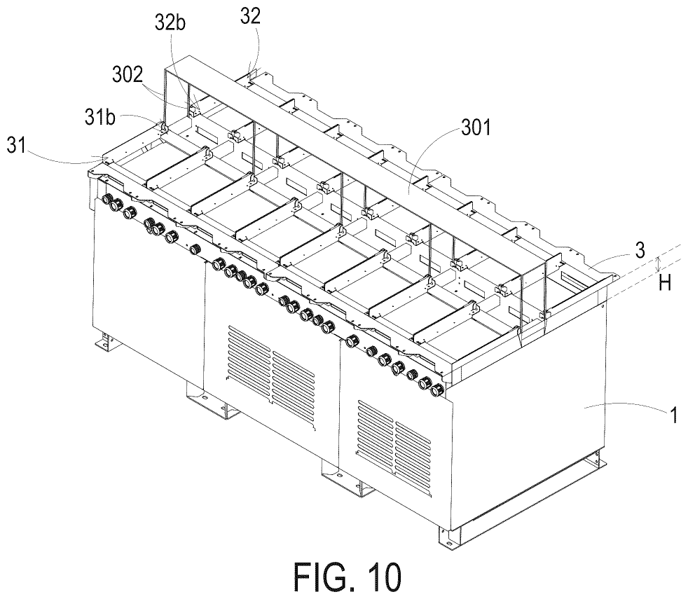

FIG. 9 is a lateral view illustrating a power equipment according to a second embodiment of the present disclosure, and the cables are hidden. FIG. 10 is a perspective view illustrating the installation cabinet and the installation bracket of the power equipment of FIG. 9. As shown in FIG. 9 and FIG. 10, in the embodiment, the power equipment 101 further includes a plurality of first air ducts 181 and a second air duct 182. The plurality of first air ducts 181 are located on top sides of the plurality of power modules 2, and the second air duct 182 is located on bottom sides of the plurality of power modules 2. Cold air is inhaled into the power modules 2 through the second air duct 182, so that the cold air exchanges heat with the plurality of power modules 2 to form hot air. Thereafter, the hot air is discharged out from the power modules 2 through the plural first air ducts 181. Through the arrangement of the first air ducts 181 and the second air duct 182, the cold air has a sufficient heat exchange capacity, and is allowed to enter the power modules 2, thereby improving the heat dissipation efficiency.

As shown in FIG. 9 and FIG. 10, in the embodiment, the plurality of first air ducts 181 include a front air duct 181a, a middle air duct 181b and a rear air duct 181c. The front air duct 181a is disposed and corresponding to a front side of the first array X, the middle air duct 181b is located between the first array X and the second array Y, and the rear air duct 181c is disposed and corresponding to a rear side of the second array Y. In the embodiment, the installation bracket 3 of the power equipment 101 has a height H, and at least part of the second air duct 182 is formed between the installation cabinet 1 and the plurality of power modules 2. With the arrangement of the first air ducts 181 and the second air duct 182, the hot air is discharged out from the tops of the power modules 2 and the cold air is inhaled from the bottom side of the power modules 2, thereby improving the heat dissipation efficiency. Further, the height H of the installation bracket 3 is adjusted to adjust a volume of the second air duct 182. In that, the air inlet volume of the cold air is adjusted to meet the heat dissipation requirements.

As shown in FIG. 9 and FIG. 10, in the embodiment, at least part of the second air duct 182 is located between the first array X and the second array Y. The installation bracket 3 includes a partition 301 and a plurality of columns 302. The plurality of columns 302 are respectively disposed and corresponding to the second end 31b of the first guiding rail 31 or the second end 32b of the second guiding rail 32, and extended in a direction away from the first guiding rail 31 or the second guiding rail 32. The partitions 301 are arranged on the plurality of columns 302, and spaced apart from the first guiding rail 31 and the second guiding rail 32. When the plurality of power modules 2 are installed on the first guiding rail 31 and the second guiding rail 32, respectively, the middle air duct 181b and the second air duct 182 are separated through the partition 301. The partition 301 is isolated between the middle air duct 181b and the second air duct 182 to prevent the hot air in the middle air duct 181b from sinking to the second air duct 182, thereby isolating the cold air from the hot air. It helps to improve the heat dissipation performance. Further, a position of the partition 301 (for example, the height of the columns 302) is adjusted to adjust a volume of the second air duct 182, and the air inlet volume of the cold air is adjusted to meet the heat dissipation requirements. The second air duct 182 includes a space formed by the installation bracket 3, the top 1a of the installation cabinet 1 and the power modules 2, and a space formed by the partition 301 and the power modules 2. All parts of the second air duct 182 are connected.

In summary, the present disclosure provides a power equipment. The plurality of power modules are arranged in double-row array and detachably disposed on the top of the installation cabinet to increase the total output power. The plurality of power modules and the installation cabinet are assembled to form a main body for transportation. It helps to improve the transportation efficiency of the power equipment, save the transportation resources, and further improve the heat dissipation efficiency.

It should be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power equipment, comprising:
an installation cabinet comprising a top; and
a plurality of power modules including a first set of power modules and a second set of power modules, wherein the first set of power module is electrically connected to the installation cabinet, arranged adjacent to each other, and detachably disposed on the top of the installation cabinet to form a first array, and the second set of power module is electrically connected to the installation cabinet, arranged adjacent to each other, and detachably disposed on the top of the installation cabinet to form a second array,
wherein the power modules in the first array and the power modules in the second array are arranged back-to-back.

2. The power equipment according to claim 1, wherein the installation cabinet and the plurality of power modules are assembled as a main body for transportation.

3. The power equipment according to claim 1, wherein each of the plurality of power modules is disposed on the top of the installation cabinet through an installation bracket.

4. The power equipment according to claim 3, wherein one of the power modules in the first array and a corresponding one of the power modules in the second array are arranged back-to-back, and the two power modules arranged back-to-back are installed on the top of the installation cabinet through an identical one of the installation brackets.

5. The power equipment according to claim 1, wherein the power modules in the first array are disposed on a front side of the top of the installation cabinet, and the power modules in the second array are disposed on a rear side of the top of the installation cabinet.

6. The power equipment according to claim 1, wherein the installation cabinet comprises a plural sets of interfaces, and the plural sets of interfaces include a first row of interfaces and a second row of interfaces; the first row of interfaces is disposed in a front side of the installation cabinet, and each of the first row of interfaces is corresponding to one of the power modules in the first array; the second row of interfaces is disposed in a rear side of the installation cabinet, and each of the second row of interfaces is corresponding to one of the power modules in the second array; and each of the plural sets of interfaces comprises a first interface, a second interface and a third interface.

7. The power equipment according to claim 6, wherein the installation cabinet comprises a first warehouse disposed on a front edge of the installation cabinet and a second warehouse disposed on a rear edge of the installation cabinet; the first warehouse comprises a first DC warehouse, a first AC warehouse disposed adjacent to the first DC warehouse, and a first wiring warehouse in communication with and installed on tops of the first DC warehouse and the first wiring warehouse; and the second warehouse comprises a second DC warehouse, a second AC warehouse disposed adjacent to the second DC warehouse, and a second wiring warehouse in communication with and disposed on tops of the second DC warehouse and the second AC warehouse.

8. The power equipment according to claim 7, wherein each of the first DC warehouse and the second DC warehouse comprises:
a plural sets of DC bus bars disposed therein; and
a plural sets of DC cables disposed therein, wherein each of the plural sets of DC cables includes a first end electrically connected to one of the plural sets of DC bus bars, and a second end reserved in the first wiring warehouse or the second wiring warehouse,
wherein after the power module is assembled, the second end of each of the plural sets of DC cables passes through the first interface in a corresponding one of the plural sets of interfaces and is electrically connected to a DC side of the power module.

9. The power equipment according to claim 7, wherein each of the first AC warehouse and the second AC warehouse comprises:
a plural sets of AC terminals disposed therein; and
a plural sets of AC cables disposed therein, wherein each of the plural sets of AC cables includes a first end electrically connected to one of the plural sets of AC terminals, and a second end reserved in the first wiring warehouse or the second wiring warehouse,
wherein after the power module is assembled, the second end of each of the plural sets of AC cables passes through the second interface in a corresponding one of the plural sets of interfaces and is electrically connected to an AC side of the power module.

10. The power equipment according to claim 7, wherein the first AC warehouse or the second AC warehouse comprises:
a control box disposed therein; and
a plural sets of control cables disposed therein, wherein each of the plural sets of control cables includes a first end electrically connected to the control box, and a second end reserved in the first wiring warehouse or the second wiring warehouse;
wherein after the power module is assembled, the second end of each of the plural sets of control cables passes through the third interface in a corresponding one of the plural sets of interfaces and is electrically connected to a control board of the power module.

11. The power equipment according to claim 1, wherein a number of the power modules in the first array is equal to a number of the power modules in the second array.

12. The power equipment according to claim 1, wherein the installation cabinet comprises a bottom structure and a transport panel, and the transport panel is connected to the bottom structure for transportation.

13. The power equipment according to claim 12, wherein when the power equipment is transported to an installation site, the transport panel is removed, and the bottom structure is fixed to a base in the installation site.

14. The power equipment according to claim 3, further comprising a plurality of first air ducts and a second air duct, wherein the plurality of first air ducts are located on top sides of the plurality of power modules, and the second air duct is located on bottom sides of the plurality of power modules, wherein cold air is inhaled into the power modules through the second air duct, and hot air is discharged out from the power modules through the plural first air ducts.

15. The power equipment according to claim 14, wherein the plurality of first air ducts include a front air duct disposed and corresponding to a front side of the first array, a middle air duct located between the first array and the second array, and a rear air duct disposed and corresponding to a rear side of the second array.

16. The power equipment according to claim 14, wherein the installation bracket has a height, and at least part of the second air duct is formed between the installation cabinet and the plurality of power modules.

17. The power equipment according to claim 14, wherein the installation bracket comprises a partition, and at least part of the second air duct is located among the partition, the first array and the second array.

18. The power equipment according to claim 16, wherein the height of the installation bracket is adjusted to adjust a volume of the second air duct.

19. The power equipment according to claim 17, wherein a position of the partition is adjusted to adjust a volume of the second air duct.
